(19) United States
(12) Patent Application Publication
(10) Pub. No.: US 2018/0226372 A1
(43) Pub. Date: Aug. 9, 2018

(54) PACKAGE STRUCTURE AND MANUFACTURING METHOD THEREOF

(71) Applicant: NANYA TECHNOLOGY CORPORATION, Taoyuan City (TW)

(72) Inventor: Po-Chun LIN, Changhua County (TW)

(21) Appl. No.: 15/428,130

(22) Filed: Feb. 8, 2017

(51) Int. Cl. H01L 23/00

(52) U.S. Cl. CPC H01L 24/11; H01L 2924/20106; H01L 24/81; H01L 24/04; H01L 2224/11003; H01L 2224/11462; H01L 2224/11602; H01L 2224/1184; H01L 2224/13017; H01L 2224/13018; H01L 2224/0401; H01L 2224/13111; H01L 2224/81047; H01L 2224/812; H01L 24/13

(57) ABSTRACT

A package structure includes a semiconductor substrate, an under bump metallurgy layer, and at least one bump. The under bump metallurgy layer is disposed on the semiconductor substrate. The bump is disposed on the under bump metallurgy layer, and the bump includes a first portion and a second portion under the first portion, wherein a top surface of the first portion of the bump includes a flat portion and a rounded portion.

### BACKGROUND

### Field of Invention

The present invention to package Lire and manufacturing method thereof.

### Description of Related Art

In recent years, flip-chip and ball grid array techniques have been increasingly used to connect an integrated circuit (IC) chip to an interconnection substrate such as printed circuit boards and to a package substrate. In flip-chip bonding an IC chip component to an interconnection substrate or printed circuit board plural (e.g., an array) solder balls (also known as “solder bumps”) are formed on a surface of a component, typically the IC chip component, and the component with the solder bumps is brought to face another component to be bonded. The two components are then heated (such as in a furnace) to reflow the solder bumps between the two components (heat the solder bumps first, then allow the solder bumps to be cooled down), thereby establishing electrical connections between respective terminals of the two components.

However, a reflow process often results in a high temperature that affects the performance of the components. Thus, to meet requirements for higher quality and reliability, advanced package forming methods and structures are needed to be developed.

### SUMMARY

An embodiment of the present disclosure provides a method for manufacturing a package structure. The method includes providing a semiconductor substrate.; forming an under bump metallurgy layer on the semiconductor substrate; forming a dielectric layer on the semiconductor substrate; forming an opening in the dielectric layer; forming at least one bump in the opening of the dielectric layer; removing the dielectric layer; and performing a compression process to the bump.

An embodiment of the present disclosure provides a package structure, the package structure includes a semiconductor substrate, an under bump metallurgy layer, and at least one bump. The under bump metallurgy layer is disposed on the semiconductor substrate. The bump is disposed on the under bump metallurgy layer, and the bump includes a first portion and a second portion disposed under the first portion, in which a top surface of the first portion comprises a flat portion and a rounded portion.

It is to be understood that both the foregoing general description and the following detailed description are by examples, and are intended to provide further explanation of the invention as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion:

FIGS. 1A to 1I are cross-sectional views illustrating sequential processes for manufacturing a package structure according to one embodiment of the present disclosure.

FIGS. 2A to 2C are cross-sectional views illustrating sequential processes for manufacturing a package structure according to another embodiment of the present disclosure.

### DETAILED DESCRIPTION

The following disclosure provides many different embodiments, or examples, for implementing different features of the provided subject matter Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” upper and the like, may be used herein for ease of description to describe one element or feature's relationship to another element(s) or feature(s) as illustrated in the figures. The spatiall relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

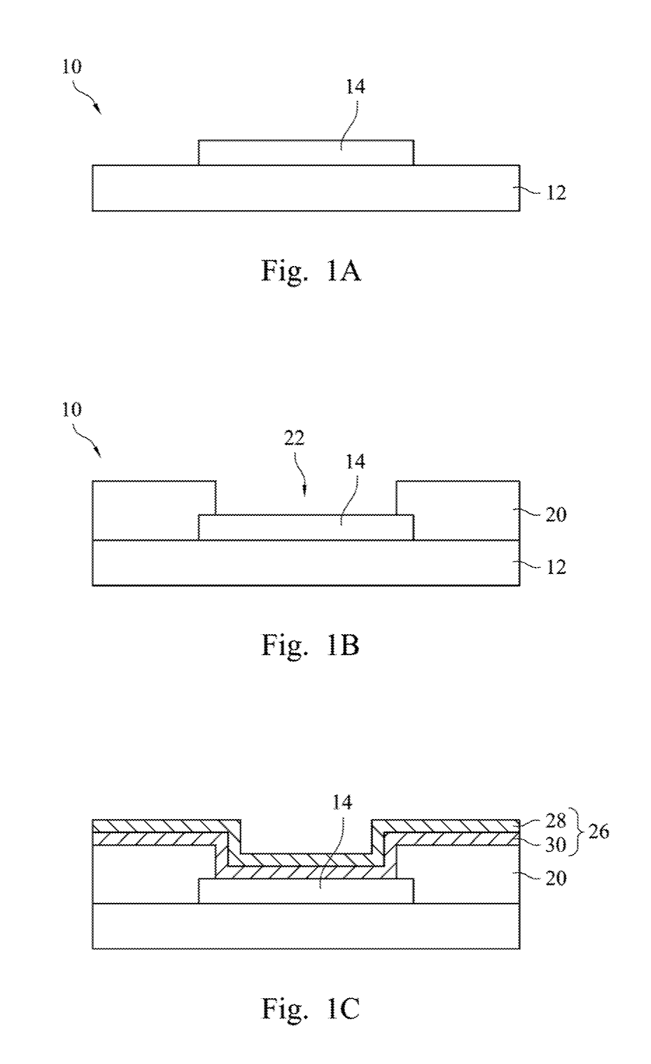

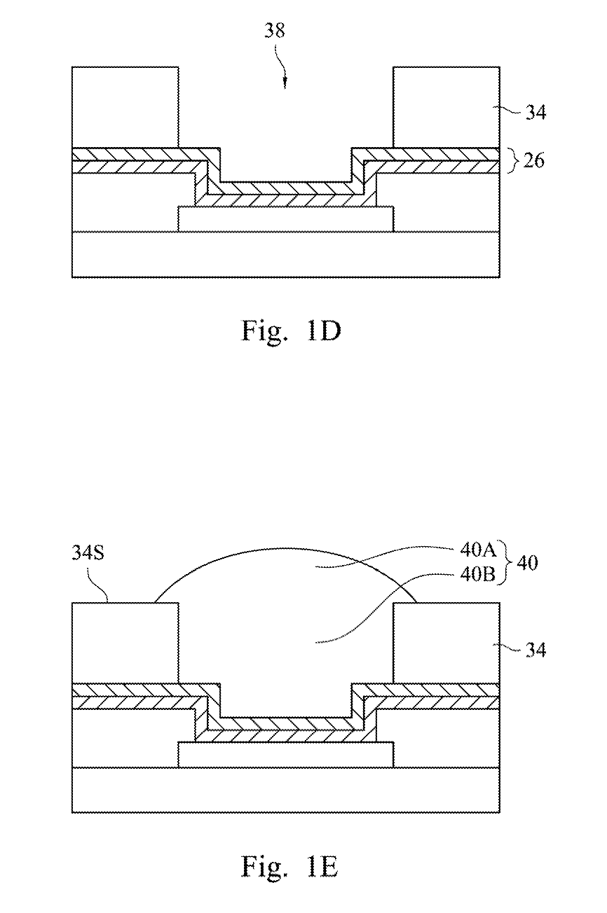

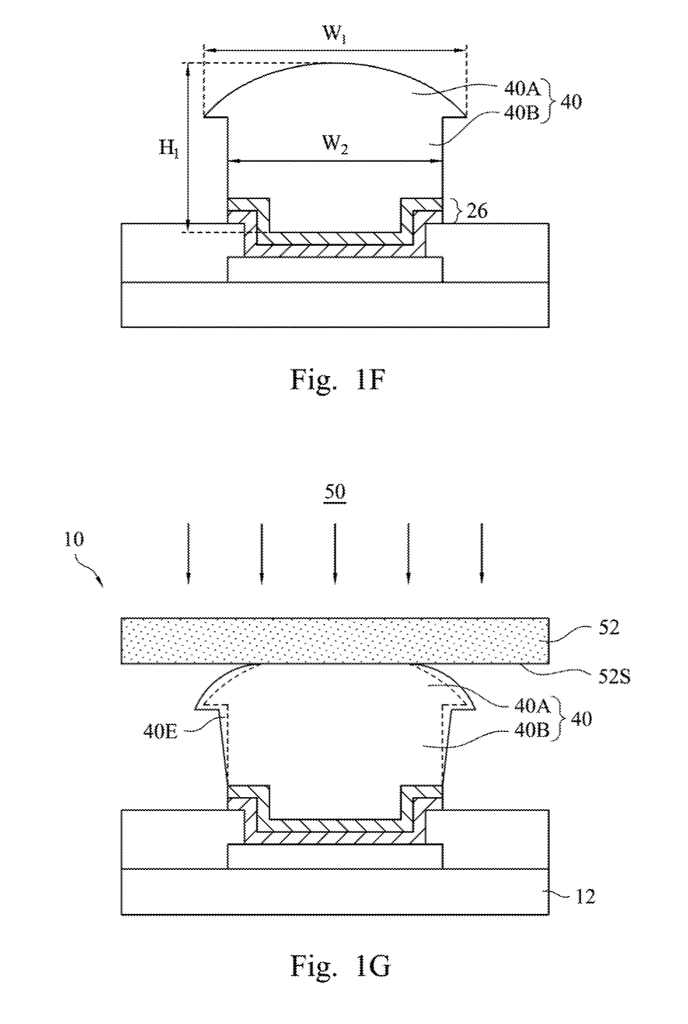

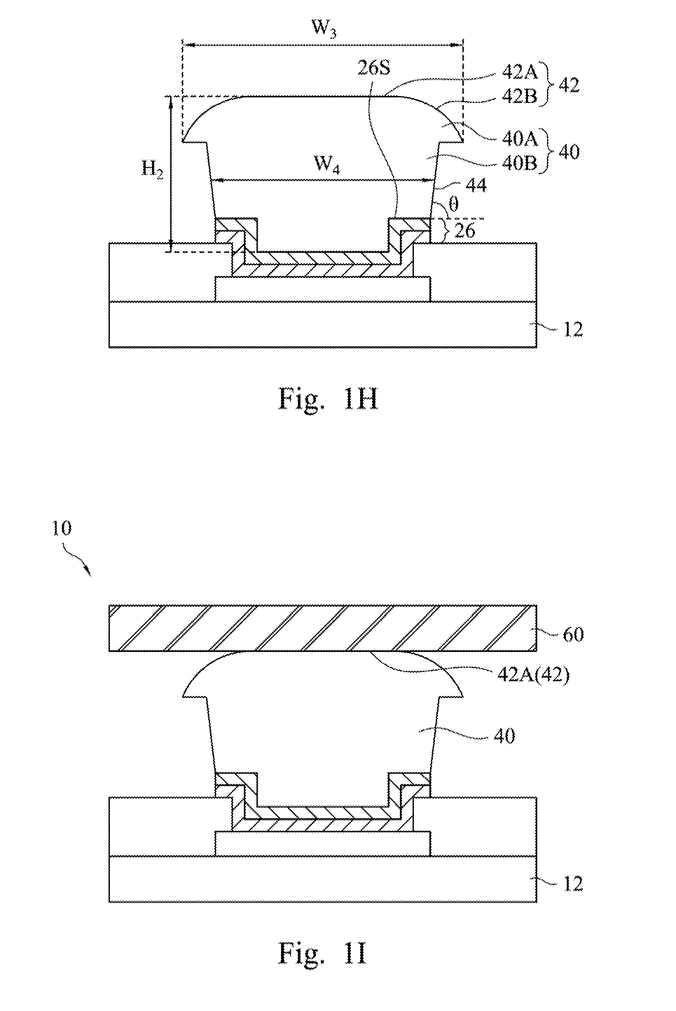

FIGS. 1A to 1I are cross-sectional views illustrating sequential processes for manufacturing a package structure according to one embodiment of the present disclosure. A package structure 10 is shown in FIG. 1A, in which the package structure 10 is formed on a semiconductor substrate 12 with active devices formed therein.

The semiconductor substrate 12 may include semiconductor material, such as silicon (Si), germanium (Ge), or silicon germanium (SiGe); a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The active devices, such as transistors, diodes, capacitors, resistors, etc., may be formed in and/or on the semiconductor substrate 12 and may be interconnected by interconnect structures formed by, for example, metallization patterns in one or more dielectric layers in the semiconductor substrate 12 to form integrated circuits.

The integrated circuits may be logic dies (e.g., central processing unit, microcontroller, etc.), memory dies (e.g., dynamic random access memory (DRAM) die, static random access memory (SRAM) the, etc.), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof.

A bond pad 14 is formed on a top surface of the semiconductor substrate 12 for establishing electrical connections to external circuits. In an example of forming the bond pad 14, a seed layer (not shown) is formed over the semiconductor substrate 12. In some embodiments, the seed layer is a metal layer, which may be a single layer or a composite layer including plural sub-layers formed from different materials. In some embodiments, the seed layer may be a titanium layer and a copper layer over the titanium layer. The, seed layer may be formed using, for example, physical vapor deposition (PVD) or the like. A photo resist is then formed and patterned on the seed layer. The photo resist may be formed by spin coating or the like and may be exposed to light for patterning,. The pattern of the photo resist defines the bond pad 14. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may include a metal, such as copper, titanium, tungsten, aluminum, or the like. Then, the photo resist and portions of the seed layer on which the conductive material is not formed are removed. The photo resist may be removed by a proper asking or stripping process, using, for example, oxygen plasma or the like. Once the photo resist is removed, exposed portions of the seed layer are removed, by using an proper etching process, such as wet or dry etching. The remaining portions of the seed layer and conductive material form the bond pad 14.

Referring to FIG. 1B, a passivation layer 20 is formed on the semiconductor substrate 12 and the bond pad 14. A photolithography process is applied to the passivation layer 20 to form an opening 22. A portion of the bond pad 14 is exposed from the passivation layer 20 through the opening 22 to allow electrical connection to the bond pad 14 to be established. The passivation layer 20 may be formed from any one of various insulating materials such as oxide, nitride or organic materials. The passivation layer 20 is applied on a top of the package structure 10 to provide both planarization and physical protection to the circuits formed on the semiconductor substrate 12.

Referring to FIG. 1C an under bump metallurgy (UBM) layer 26 is then deposited on the top surface of the passivation layer 20 and the exposed top surface of the bond pad 14. The under bump metallurgy layer 26 includes an adhesion/diffusion barrier layer 30 and a wetting layer 28. The adhesion/diffusion barrier layer 30 may be formed from Ti, TiN or other metal such as Cr. The Wetting layer 28 is formed from a Cu layer or a Ni layer. The under bump metallurgy layer 26 is used to improve bonding between a bump to be formed at the top surface of the bond pad 14 in subsequent steps.

Referring to FIG. 1D a dielectric layer 34 is deposited on a top of the under bump metallurgy layer 26. In some embodiments, the dielectric layer 34 is formed from a polymer, which may be a photo-sensitive material such as PBO, polyimide, BCB, or the like, and may be patterned using a lithography mask. In other embodiments, the dielectric layer 34 is formed from a nitride such as silicon nitride, an oxide such as silicon oxide, PSG, BSG, BPSG; or the like. The dielectric layer 34 may be formed by spin coating lamination, chemical vapor deposition (CVD), the like, or a combination thereof.

The dielectric layer 34 is then patterned to form an opening 38 to expose portions of the under bump metallurgy 26. The opening 38 defines a position of the bump to be subsequently formed. The patterning may be performed by a proper process such as exposing the dielectric layer 34 to light when the dielectric layer 34 is a photo-sensitive material, or for example, anisotropic etching.

Reference is made to FIG. 1E. In the following electrodeposition process, a bump 40 is electro deposited into the opening 38 to form a structure protruding from a top surface 34S of the dielectric layer 34. The bump 40 may be a BGA connector, a solder ball, a metal pillar, a controlled collapse chip connection (C4) bump, a micro bump, an electroless nickel-electroless palladium-immersion gold technique (ENEPIG) formed bump, or the like. The bump 40 may include a conductive metal such as solder including copper, aluminum, gold, nickel, silver, palladium, tin, the like, or a combination thereof. In some embodiments, the bump 40 is formed by initially forming a layer of solder by a method such as evaporation, electroplating, printing, solder transfer, ball placement, or the like.

Generally, the bump 40 has a first portion 40A and a second portion 40B disposed below the first portion 40A, in which the first portion 40A protruds from the top surface 34S of the dielectric layer 34, and the second portion 40B is embedded in the dielectric layer 34. More particularly,since the first portion 40A protrudes from the top surface 34S of the dielectric layer 34 parts of the first portion 40A may further be formed over the top surface 34S of the dielectric layer 34. Thus, a width of the first portion 40A is greater than that of the second portion 40B.

In some embodiments, the thickness of the dielectric layer 34 is carefully controlled. For example, if the dielectric layer 34 is a photoresist layer, the thickness of the dielectric layer 34 may be in the range between about 30 pm and about 40 pm, but the present disclosure is not limited thereto. The reason for tightly controlling the thickness of the dielectric layer 34 is that, for achieving a fine-pitched bump formation, a dielectric layer (e.g. a photoresist layer) of a reasonably small thickness is required to achieve high imaging resolution. It is known that for example, during a photolithography process, the thicker the photoresist layer is the poorer accuracy the imaging process has. To maintain a reasonable accuracy in the imaging process on the dielectric layer 34, reasonably thin dielectric layer 34 is required, thus resulting in a mushroom configuration of the bump 40 deposited therein.

Referring to FIG. 1F, the dielectric layer 34 is removed. In some embodiments, if the dielectric layer 34 is formed from a photo-sensitive material, such as photoresist, the dielectric layer 34 may be removed by an proper ashing or stripping process, using an oxygen plasma or the like. In some other embodiments, the dielectric layer 34 may be removed by a suitable method, such as etching.

After the dielectric layer 34 is removed, the under bump metallurgy 26 is etched away by using the bump 40 as a mask in a suitable process, such as a wet etching process. Thus, portions of the under bump metallurgy 26 under the dielectric layer 34 (shown in FIG. 1E) are removed, and the other portions of the under bump metallurgy 26 under the bump 40 remain.

As shown in FIG. 1F, the bump 40 has a first height H1 which may also be referred to an original height. Moreover, the first portion 40A of the bump 40 has a first width W1, and the second portion 40B of the bump 40 has a second width W2 in which the first width W1 greater than the second width W2. In other words a vertical projection of the first portion 40A on the semiconductor substrate 12 is greater than a vertical projection of the second portion 40B on the semiconductor substrate 12,

On the other hand, the top surface of the first portion 40A is substantially a round shape. The sidewall of the second portion 40B is substantially perpendicular to the semiconductor substrate 12. Accordingly, the sidewall of the second portion 40B of the bump 40 are shown as substantially straight lines in a cross-sectional view.

Referring to FIG. 1G a compression process 50 is applied to the package structure 10. More particularly, the compression process 50 is applied to the top surface of the bump 40. The compression process 50 includes providing a plate 52. The plate 52 may be controlled by a tool, such that the plate 62 is moved toward the package structure 10 and further reshape the profile of the top surface of the bump 40 by providing a downward force to the bump 40. In this embodiment, the plate 52 has a flat surface 52S, in which the flat surface 52S faces and contacts the top surface of bump 40 and followed with a downward force, so as to form a flat surface on the bump 40. The top surface of the bump 40 is partially in contact with the plate 52, thereby forming a fiat portion at a center, and forming a rounded portion at an edge.

It should be noted that the plate 52 should be harder than the bump 40, such that the bump 40 may be reformed to a shape corresponding to the profile of the plate 52, such as the flat surface 52S. In some embodiments, the material of the plate 52 has a larger Young's modulus than the material of the bump 40. In the present embodiment, the flat surface 52S of the plate 52 is substantially parallel to the longitudinal direction of the semiconductor substrate 12.

As described above, the bump 40 may be formed from conductive metal such as solder, copper, aluminum, gold, nickel, silver, palladium, tin, the like, or a combination thereof. In the compression process 50, due to the malleability of metal, the bump 40 is deformed and may extend laterally. As a result, the bump 40 includes an extension portion 40E. The extension portion 40E is defined as the shape change between the original bump 40 (shown by the dash line) and the deformed bump 40 (shown by the solid line). In some embodiments, the extension portion 40E is evenly distributed on the opposite sides of the bump 40. In the present embodiment, the extension portion 40E is present at the first portion 40A and the second portion 40B of the bump 40. That is, both the first portion 40A and the second portion 406 of the bump 40 extend during the compression process 50.

It should be understood that, the shape of the deformed bump 40 (the solid line) is merely used for explanation and the present disclosure is not limited thereto. The shape of the deformed bump 40 (or the extension portion 40E) may be varied according to actual situations. Also the condition of the compression process 50, such as the material of the bump, the shape of the plate, or the downward force of the compression process, may be controlled to obtain a desired profile of the bump.

Referring to 1H, after the compression process 50 (shown in FIG. 1G), a final bump 40 is completed. After the compression process, the final bump 40 has a second height H2 in which the second height H2 is smaller than the first height H1 (the original height of the bump 40 shown in FIG. 1F).

The first portion 40A and the second portion 406 of the final bump 40 have a third width W3 and a fourth width W4, respectively. The third width W3 is greater than the fourth width W4. It should be noted that the fourth width W4 is the average width of the second portion 40B. Further, due to the extension of the bump, the third width W3 is greater than the first width W1 (the original width of the first portion 40A shown in FIG. 1F), and the fourth width W4 is greater than the second width W2 (the original width of the second portion 40B shown in FIG. 1F), respectively.

On the other hand, the first portion 40A of bump 40 has a top surface 42, in which the top surface 42 further includes a flat portion 42A and a rounded portion 42B. The fiat portion 42A is formed according to the flat surface 52S of the plate 52 shown in FIG. 1G. In the present embodiment, the flat portion 42A of the top surface 42 is substantially parallel to the longitudinal direction of the semiconductor substrate 12. The rounded portion 42B is the portion that is not in contact with the plate 50 during the compression process 50, such that the rounded portion 42B substantially remains as the original profile of the bump 40 shown in FIG. 1F. In some embodiments, the rounded portion 42B is substantially surrounds the first portion 40A of the bump 40. The second portion 40B of the bump 40 has a sidewall 44. In the present embodiment, an angle θ between the sidewall 44 and the top surface 26S of the under bump metallurgy layer 26 is substantially smaller than 90 degrees. In some embodiments, the sidewall 44 has a slant straight surface.

Referring to FIG. 1I, an electrical component 60 is connected to the bump 40, such that the package structure 10 is completely formed. Due to the compression process 50 (shown in FIG. 1G), the flat portion 42A of the top surface 42 of the bump 40 provides a better interface to connect t he bump 40 to the electrical component 60. Moreover, the overall process (before and after connecting the bump 40 to the electrical component 60) is performed under a temperature that is lower than the melting point of the material of the bump 40. For example, if the bump 40 is formed from Sn, the overall process is performed below 231.9° C. Since the integrated circuits formed in the semiconductor substrate 2 and the electrical component 60, such as DRAM or SRAM, are likely damaged during a high temperature process, such as reflow. The present disclosure provides a method for forming a bump with flat top surface that can be easily connected with other device. Also, such method is performed under the melting point of the material of the bump, such that the device performance may be improved.

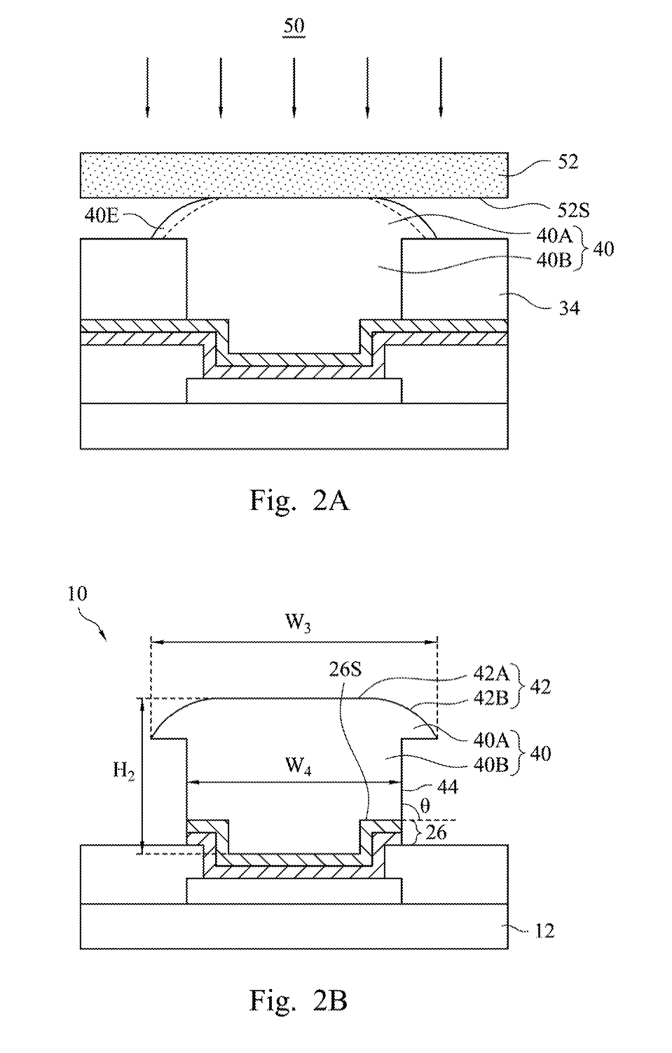

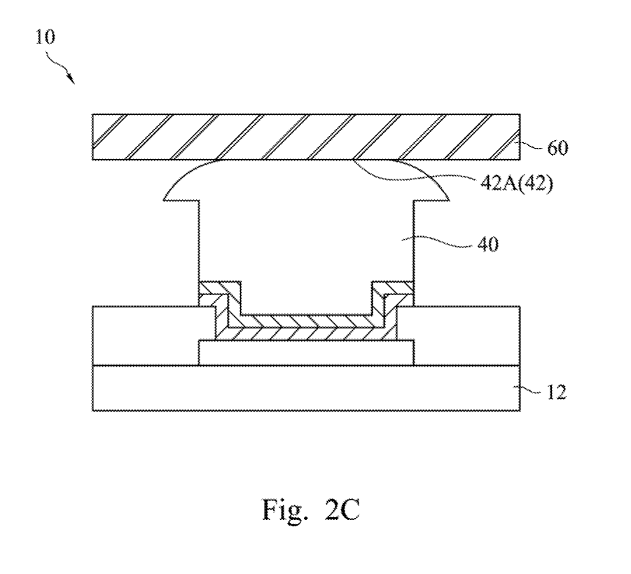

FIGS. 2A to 2C are cross-sectional views illustrating sequential processes for manufacturing a package structure according to another embodiment of the present disclosure. The embodiment of FIGS. 2A to 2C is different from the embodiment of FIGS. 1A to 1I, in that the compression process 50 is performed before the dielectric layer 34 is removed, as shown in FIG. 2A.

A compression process 50 is applied to the package structure 10. More particularly, the compression process 50 is applied to the top surface of the bump 40. The compression process 50 includes providing a plate 52. The plate 52 may be controlled by a tool, such that the plate 52 is moved toward the package structure 10 and further deform the profile of the top surface of the bump 40 by providing a downward strength to the bump 40. In this embodiment, the plate 52 has a flat surface 52S, in which the flat surface 52S faces and contacts the top surface of bump 40 and followed with a downward force, so as to form a flat surface on the bump 40. The top surface of the bump 40 is partially in contact with the plate 52, thereby forming a flat portion at a center, and forming a rounded portion at an edge.

It should be noted that the plate 52 should be harder than the bump 40, such that the bump 40 may be deformed to a shape corresponding to the profile of the plate 52, such as the flat surface 52S. In some embodiments, the material of the plate 52 has a larger Young's modulus than the material of the bump 40. In the present embodiment, the fiat surface 52S of the plate 52 is substantially parallel to the longitudinal direction of the semiconductor substrate 12.

As described above, the bump 40 may be made of conductive metal such as solder, copper, aluminum, gold, nickel, silver, palladium, tin, the like, or a combination thereof. In the compression process 50, due to, the malleability of metal, the bump 40 is reformed and may extend laterally. As a result, the bump 40 includes an extension portion 40E. The extension portion 40E is defined as the shape change between the original bump 40 (shown by the dash line) and the reformed bump 40 (shown by the solid line). In some embodiments, the extension portion 40E is evenly distributed on the opposite sides of the bump 40. In the present embodiment, since the second portion 40B is confined by the dielectric layer 34, the extension portion 40E is present only at the first portion 40A of the bump 40.

Referring to 2B, after the compression process 50 (shown in FIG. 2A), a final bump 40 is completed. After the compression process, the final bump 40 has a second height H2, in which the second height H2 is smaller than the first height H1 (the original height of the bump 40 shown in FIG. 1F).

The first portion 40A and the second portion 40B of the final bump 40 have a third width W3 and a fourth width W4, respectively. The third width W3 is greater than the fourth width W4. Further, due to the extension of the bump, the third width W3 is greater than the first width W1 (the original width of the first portion 40A shown in FIG. 1F). However, due to the confinement of the dielectric layer 34, the fourth width W4 is substantially equal to the second width W2 (the original width of the second portion 40B shown in FIG. 1F). That is, the width of the second portion 40B remains the same after the compression process. Moreover, due to the confinement of the dielectric layer 34, the structure of the bump 40 may be more stable during the compression process.

On the other hand, the first portion 40A of the bump 40 has a top surface 42 in which the top surface 42 further includes a flat portion 42A and rounded portion 42B. The fiat portion 42A is formed according to the flat surface 52S of the plate 52 shown in FIG. 1G. In the present embodiment, the flat portion 42A of the top surface 42 is substantially parallel to the longitudinal direction of the semiconductor substrate 12. The rounded portion 42B is the portion that is not in contact with the plate 50 during the compression process 50, such that the rounded portion 42B substantially remains the original profile of the bump 40 shown in FIG. 1F. In some embodiments, the rounded portion 42B is substantially surrounds the first portion 40A of the bump 40. The second portion 40B of the bump 40 has a sidewall 44. In the present embodiment, the sidewall 44 is substantially vertical to the semiconductor substrate 12, and has a straight surface. That is, an angle θ between the sidewall 44 and the top surface 266 of the under bump metallurgy layer 26 is substantially equal to 90 degrees.

Referring to FIG. 2B, an electrical component 60 is connected to the bump 40, such that the package structure 10 is completely formed. Due to the compression process 50 (shown in FIG. 2A), the flat portion 42A of the top surface 42 of the bump 40 provides a better interface to connect the bump 40 to the electrical component 60. Moreover, the overall process (before and after connecting the bump 40 to the electrical component 60) is performed under a temperature that is lower than the melting point of the material of the bump 40. For example, if the bump 40 is made of Sn, the overall process is performed under 231.9° C. Since the integrated circuits formed in the semiconductor substrate 12 and the electrical component 60, such as DRAM or SRAM, are easily damaged during a high temperature process, such as reflow. The present disclosure provides a method for forming a bump with flat top surface that is easily to be connected with other device. Also, such method is performed under the melting point of the material of the bump, such that the device performance may be improved.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A method for manufacturing a package, the method comprising:
forming a dielectric layer on a semiconductor substrate;
forming an opening in the dielectric layer;
forming at least one bump in the opening of the dielectric layer;
removing the dielectric layer; and
performing a physical compression process on the bump, and connecting an electrical component to the bump at a temperature lower than a melting point of the bump.

2. The method of claim 1, wherein performing the physical compression process comprises:
providing a plate; and
compressing a top surface of the bump with the plate.

3. The method of claim 2, wherein a surface of the plate facing the bump is substantially flat, and is parallel to the semiconductor substrate.

4. The method of claim 2, wherein a Young's modulus of the plate is greater than a Young's modulus of the bump.

5. The method of claim 2, wherein the top surface of the bump partially contacts the plate, thereby forming a flat portion at a center of the bump, and forming a rounded portion at an edge of the bump.

6. The method of claim 1, wherein removing the dielectric layer is performed after performing the physical compression process on the bump.

7. The method of claim 6, wherein a first portion of the bump protruding from the dielectric layer is extended when the physical compression process is performed.

8. The method of claim 1, wherein removing the dielectric layer is performed before performing the physical compression process on the bump.

9. The method of claim 8, wherein the bump is extended when the physical compression process is performed.

10-11. (canceled)

12. The method of claim 1, wherein the bump is made of Sn, and connecting the electrical component to the bump is performed at the temperature lower than 231.9° C.

13. The method of claim 1, further comprising:
forming an under bump metallurgy layer on the semiconductor substrate before forming the dielectric layer on the semiconductor substrate.

14. A package structure, comprising:
a semiconductor substrate; and
at least one bump disposed on the substrate, wherein the bump comprises a first portion and a second portion disposed under the first portion, a width of the first portion is greater than a width of the second portion, and a top surface of the first portion comprises a flat portion and a rounded portion.

15. The package structure of claim 14, wherein the rounded portion surrounds of the flat portion.

16. (canceled)

17. The package structure of claim 14, wherein an angle between a sidewall of the bump and a top surface of the bump metallurgy layer is substantially equal to 90 degrees.

18. The package structure of claim 14, wherein an angle between a sidewall of the bump and a top surface of the bump metallurgy layer is substantially smaller than 90 degrees.

19. The package structure of claim 18, wherein the sidewall of the bump has a slant straight surface.

20. The package structure of claim 14, further comprising:
an under bump metallurgy layer disposed between the substrate and the bump.
